(19) United States
(12) Patent Application Publication
(10) Pub. No.: US 2013/0174900 A1
(43) Pub. Date: Jul. 11, 2013

(54) NANOWIRE ENHANCED TRANSPARENT CONDUCTIVE OXIDE FOR THIN FILM PHOTOVOLTAIC DEVICES

(71) Applicants: Chester A. Farris, III, Yorba Linda, CA (US); Robert D. Wieting, Simi Valley, CA (US); Ashish Tandon, Sunnyvale, CA (US)

(72) Inventors: Chester A. Farris, III, Yorba Linda, CA (US); Robert D. Wieting, Simi Valley, CA (US); Ashish Tandon, Sunnyvale, CA (US)

(73) Assignee: Stion Corporation, San Jose, CA (US)

(21) Appl. No.: 13/543,462

(22) Filed: Jul. 6, 2012

Related U.S. Application Data
(60) Provisional application No. 61/505,475, filed on Jul. 7, 2011.

(51) Int. Cl. H01L 31/18; H01L 31/0224

(52) U.S. Cl. CPC H01L 31/1884; H01L 31/022466; B82Y 99/00
USPC 136/256; 438/98; 977/762; 977/890; 977/954

(57) ABSTRACT

A thin-film photovoltaic devices includes transparent conductive oxide which has embedded within it nanowires at less than 2% nominal shadowing area. The nanowires enhance the electrical conductivity of the conductive oxide.

### CROSS-REFERENCES TO RELATED APPLICATIONS

This application claims the benefit of U.S. Provisional Application No. 61/505,475, filed Jul. 7, 2011, entitled “Nanowire Enhanced Transparent Conductive Oxide for Thin Film Photovoltaic Devices.” The entire disclosure of which is incorporated herein by reference for all purposes.

### BACKGROUND OF THE INVENTION

This invention relates generally to thin-film photovoltaic techniques and more particularly, to a method and structure of a nanowire-enhanced transparent conductive film for thin-film photovoltaic devices. Embodiments of the present invention can be applied to embed metallic nanowires in a transparent conductive oxide film for the manufacture of thin-film photovoltaic devices.

In the process of manufacturing thin-film photovoltaic devices based on copper-indium-selenium (CIS) and/or copper-indium-gallium-selenium (CIGS) absorber materials, there are various manufacturing challenges, such as scaling up the manufacturing to large substrate panels while maintaining structure integrity of substrate materials, ensuring uniformity and granularity of the thin film material, and forming an overlying electrode characterized by both high lateral conductivity and good optical transmission. While conventional techniques in the past have addressed some of these issues, they are often inadequate. For example, U.S. Pat. No. 6,936,761 discloses a technique of disposing conductive wires having 50 microns or less in diameter in a transparent conductive polymer material for enhancing electrical conductivity while limiting geometrical shadowing area for the absorber material. The size of the conductive wires, however, is in tens of microns range which is still relatively large and difficult in practice to achieve a reduction in resistance without causing the absorption of incoming light by the added wires.

### BRIEF SUMMARY OF THE INVENTION

The invention provides a method and structure for enhancing lateral conductivity and optical transparency in electrodes of a thin-film photovoltaic device. Embodiments of the invention can embed conductive nanowires with about 1% effective shadowing area in a transparent conductive oxide film for the manufacture of thin-film photovoltaic devices.

In one embodiment, the invention provides a structure for fabricating thin-film photovoltaic devices. The structure includes an absorber material with a copper-based thin-film photovoltaic compound overlying a conductive material formed on a substrate. A buffer material overlies the absorber material and a transparent conductive oxide is formed over the buffer material. The structure includes a plurality of nanowire conductors embedded in the window layer in an essentially random configuration partially overlapping and crossing each other with less than 2% nominal shadowing area to visible light. Each nanowire conductor has an electrical conductivity about 1000 times higher than the transparent conductive oxide material.

The present invention provides a method for manufacturing thin-film photovoltaic devices in which a barrier layer is formed over a substrate structure, and a first conductive electrode is formed over the barrier layer. Material species including copper, sodium, indium, gallium are deposited on the first electrode and an absorber layer is formed by treating the material in a gaseous environment having selenium and sulfur species, using a predetermined temperature profile. A buffer material is deposited over the absorber and a conductive oxide formed over the buffer material. Nanowires at least partially covering the first conductive oxide material with a less than 2% nominal shadowing area for visible light are then deposited. The nanowires have electrical conductivity on the order of 1000 times higher than the conductive oxide. The method includes forming a second conductive oxide over the nanowires and partially overlying the first conductive oxide to create a second electrode.

In an alternative embodiment the method includes applying nanowire structures over the upper surface with a coverage of about 1% and greater. A transparent conductor material is formed over the nanowires to embed them in the transparent conductor material. The nanowires structures facilitate scattering of incident electromagnetic radiation while allowing the electromagnetic radiation to traverse the thickness of the transparent conductor material and yet not block the absorber material.

The method and structure provided are incorporated in a series of innovative manufacturing processes for making next generation high efficiency thin-film photovoltaic devices. In various embodiments, an nanowire-enhanced transparent conductive oxide film is formed by first adding a TCO film followed by embedding nanowires on the TCO film or simultaneously adding conductive nanowires and forming TCO film. The nanowires are configured in substantially random patterns with about 1% or more physical coverage in the surface area subjected to incoming light. The nanowires are made by high conductivity material, for example, copper, silver or metal alloys, although carbon or organic material can be also be used. In one embodiment, the nanowires are 100 nm or less in diameter with a random crossing configuration, a structure that facilitates off-resonance scattering of electromagnetic waves on the nanowires via surface Plasmon effects and causes substantially no absorption loss of the incoming light. In addition to the small geometric shadowing area of the nanowires, the scattering effect reduces the cross section area blocking light into the absorber material and enables using a host TCO film with substantially lower doping than non-nanowire-enhanced TCO film. As the result, the nanowire-enhanced TCO film has an enhanced lateral conductivity and carrier mobility so that the device can capture more light-converted current with improved efficiency.

### BRIEF DESCRIPTION OF THE DRAWINGS

FIG. 1 is a cross-section view of a thin-film photovoltaic device with nanowire-enhanced transparent conductive oxide (TCO) electrode;

FIG. 1A is a perspective view of a thin-film photovoltaic device with nanowire-enhanced TCO electrode on a monolithically integrated panel;

FIG. 1B is a top view of a thin-film photovoltaic device with nanowire-enhanced TCO electrode on a square wafer;

FIG. 1C is a top view of a silicon based or 3/5 group material based photovoltaic cell with nanowire-enhanced TCO electrode;

FIG. 2A illustrates a unit area of the film;

FIG. 2B is a diagram of a nanowire;

FIG. 2C illustrates a simplified shadowing model of nanowires within a unit area of the film;

FIG. 3A is a top view of a layout of the nanowires on a TCO film;

FIG. 3B is a top view of another layout of the nanowires on a TCO film;

FIGS. 4A through 4C are cross-sectional views of TCO films including nanowires; and

FIG. 5 is a flow chart illustrating a method for manufacturing a thin-film photovoltaic device.

### DETAILED DESCRIPTION OF THE INVENTION

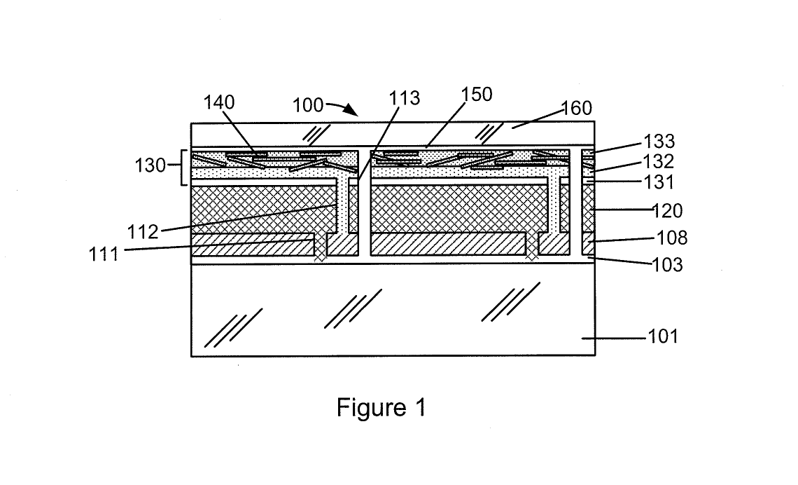

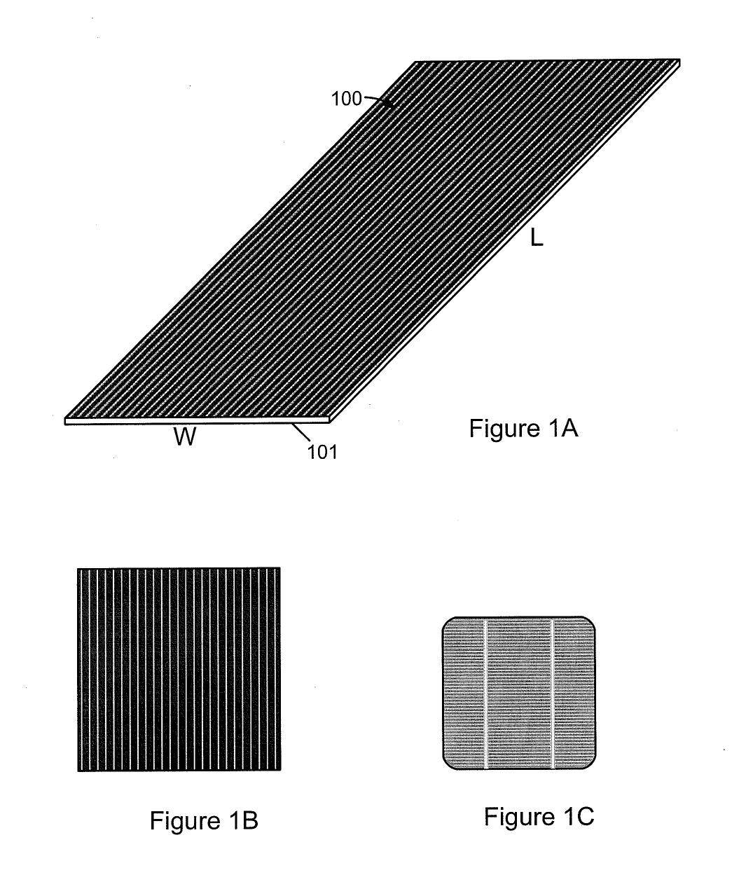

FIG. 1 is a cross-section view of a thin-film photovoltaic device with a nanowire-enhanced transparent conductive oxide (TCO) film according to an embodiment of the invention. The thin-film photovoltaic device 100 is formed through thin-film manufacturing processes including forming a nanowire-enhanced optically transparent conductive electrode over the photovoltaic absorber material. As shown, the thin-film photovoltaic device 100 includes cells patterned from a series of continuous thin films formed on a substrate structure 101, including at least a barrier later 103, a bottom electrode 110, an absorber material 120, a top electrode 130, and a cap glass 160. As known, transparent conductive oxide (TCO) material is widely used for forming a thin-film electrode as the top electrode of a photovoltaic cell. By incorporation of high conductivity nanowires into the TCO film, enhancement of lateral conductivity without appreciable reduction in optical transmission is achieved.

The substrate structure used for forming the thin-film photovoltaic device can be a glass substrate, a quartz or plastic substrate, or a semiconductor wafer. The glass substrate can be soda-lime glass, an acrylic glass, a sugar glass, or other material, e.g. a specialty Corning™ glass. In another embodiment, the glass substrate 101 is a monolithically integrated panel directly provided for forming a multi-cell thin-film photovoltaic device. In a specific implementation, as seen in FIG. 1A, the glass panel has a standard rectangular shaped form factor, although other geometric shapes can be utilized depending on the application. In a particular example, the width W of the shaped glass substrate 101 is at least 65 cm and the length L is at least 165 cm. The thin-film photovoltaic device 100 formed on this shaped glass substrate 101 can be packaged by itself or by coupling two such devices together into a deliverable module. Other shaped panels, e.g., 25 cm×25 cm, are often used (FIG. 1B). The photovoltaic device is not limited to thin-film type, and can include silicon-based or three-five group material based photovoltaic cells formed on standard sized wafer (FIG. 1C).

Referring to FIG. 1, the thin-film photovoltaic device 100 includes a barrier layer 103 formed overlying the substrate structure 101, followed by a conductive material 110 overlying the barrier layer 103. In a specific embodiment, the substrate structure 101 is made by soda lime window glass, typically containing alkaline ions comprising greater 10 wt % sodium oxide, or about 15% wt % sodium. The barrier layer 103 used for preventing sodium ions in the soda lime glass material from diffusing uncontrollably into photovoltaic material area formed in subsequent processes. Depending on the embodiments, the barrier layer 103 can be oxide/nitride compounds selected from silicon oxide, aluminum oxide, titanium nitride, silicon nitride, tantalum oxide, and zirconium oxide deposited using technique such as a sputtering process, e-beam evaporation, a chemical vapor deposition process (including plasma enhanced processes), and others. The conductive material 110 is made by metal or metal alloy using sputtering techniques. In an example, molybdenum material or molybdenum selenide is used. Alternatively, other materials including transparent conductor oxide (TCO) such as indium tin oxide (commonly called ITO), florine doped tin oxide (FTO), and the like can be used.

Following the formation of the conductive material 110 overlying the barrier layer 103, a patterning process can be performed to scribe the films (including the conductive material and barrier layer) to form a plurality of line trenches 111 into the continuous films. In a specific embodiment, these line trenches are formed in a parallel stripe patterns across the substrate, forming a natural boundary of a plurality of stripe-shaped photovoltaic cells and being partially utilized for coupling electrically the plurality of stripe-shaped photovoltaic cells. The patterned conductive material 110 is configured to be a lower electrode for each of the plurality of stripe-shaped photovoltaic cells. Additional thin films are to be formed over the stripe patterns and additional patterning processes are to be performed for completing the cell-cell coupling structure at regions located substantially within a vicinity of the plurality of line trenches 111. FIG. 1A shows a perspective view of the solar panel with the thin-film photovoltaic device 100 formed on a monolithically integrated glass panel 101 having a rectangular form factor (W×L). In fact, FIG. 1A schematically shows that a plurality of stripe-shaped cell patterns is respectively divided by light-colored lines in parallel with the L side of the substrate which correlate to the line trenches 111 as well as additional line patterns formed within the vicinity of the line trenches 111.

Referring to FIG. 1 again, a photovoltaic absorber material 120 is formed overlying the patterned conductive material 110. In an embodiment, the photovoltaic absorber material 120 is formed from copper-based precursor materials including copper species, indium species, and/or gallium species doped with sodium species. All the ingredients of the precursor material are deposited using sputtering techniques at relative low temperatures according to a specific embodiment. Then the precursor material is treated in a two-step selenization and sulfurization process. This is a thermal process within a gaseous environment containing selenium species and sulfur species so that the precursor materials react with the gaseous selenium and sulfur species and are transformed into a copper-indium-gallium-selenium (CIGS) and/or copper-indium-gallium-selenium-sulfur (CIGSS) compound material with a preferred Cu/(In+Ga) composition ratio of about 0.9. In another embodiment, the CIGS/CIGSS compound material comprises a plurality of grains with sizes of about 0.75 microns of well-crystallized chalcopyrite structure of CuInGaSe₂ or CuInGa(SSe)₂. The CIGS/CIGSS compound material bears a p-type semiconductor electric characteristic and a proper energy gap for serving as a photovoltaic absorber. In an alternative embodiment, the photovoltaic absorber material can be more traditional silicon-based photo-electric active material or three-five group material based photovoltaic absorber.

Following the formation of the photovoltaic absorber material 120, another patterning process can be performed to form another plurality of line patterns 112 which are respectively shifted from the line trenches 111 formed in previous patterning process. A buffer material 131 is applied overlying the patterned absorber material 120. The buffer material 131 is CdS or Cd-free ZnO mixed with ZnS applied using chemical bath method or alternative dipping process. A first transparent conductive oxide (TCO) film 132 is then formed using a MOCVD process overlying the buffer material 120, although other thin-film deposition techniques including sputtering, plating, chemical bath deposition can also be applied depending on embodiments. In an embodiment, the first TCO film 132 is part of the process for forming a transparent electrode near the top-most surface of the monolithically integrated photovoltaic device. The top electrode of each (stripe-shaped) photovoltaic cell is firstly exposed to sun light and in a preferred embodiment to allow substantially all visible spectrum of the light traverse the film and reach the absorber material beneath. Secondly, this is an electrode designated for collecting the electric current generated by the absorber material which absorbs the light and converts photons into electrons. Thus, the top electrode is preferred to be made of one or more materials characterized by substantial transparency to light in visible spectrum and high lateral electrical conductivity. TCO film has been applied as a top electrode material in the manufacture of thin-film photovoltaic devices, as seen in U.S. patent application Ser. No. 13/086,135, filed Apr. 13, 2011, assigned to Stion Corporation in San Jose and incorporated as reference for all purposes. A typical TCO film is zinc oxide film formed using a MOCVD process, where the ZnO film is doped with Boron or Aluminum to achieve different conductivity levels. For example, a low doping level ZnO film with higher sheet resistivity may be formed first over the absorber material 120 for forming an Ohmic contact for the top electrode. Then, a higher doping level ZnO film is added for increasing the lateral conductivity within the whole TCO film. On the one hand, there is a tradeoff of having higher doping level in the TCO film. That is a reduction in free-carrier mobility which leads to an increased optical absorption by the free carriers in the long wavelength region of the visible light. On the other hand, by increasing TCO film thickness the lateral conductivity can be enhanced while the larger thickness results in less optical transmission as a tradeoff.

In a specific embodiment, followed by formation of a TCO film 132 having a reduced doping level and a reduced thickness, nanowires 140 with conductive material are disposed over the TCO film 132. The nanowires 140 can be pre-made metallic nanowires which are sprayed onto an upper surface of the TCO film 140. In another embodiment, the metallic nanowires can be formed by an in-situ chemical deposition or atomic deposition or a deposition followed by a lithography patterning process. The nanowires are made of a metal or alloy material such as gold, silver, copper, aluminum, molybdenum, tungsten and typically have an electrical conductivity about 1000 times greater than the TCO film itself. Each nanowire has a diameter or cross section dimension of about 100 nm and an aspect ratio typically ranging from 1:1 to 1000:1. In a specific embodiment, the spraying of the nanowires is limited to an amount corresponding to 2% or less in terms of a shadowing area. In an embodiment, the nanowires are laid out on the TCO film in a substantially ordered form, e.g., with their length in parallel mutually and to the upper surface very much aligned along a current flow direction. In another embodiment, the nanowires may be laid out on the TCO film in a relatively random pattern with their length oriented nearly in the upper surface but pointed in different directions. In yet another embodiment, these nanowires may be overlapped or may not be directly connected to each other. Overall, due to higher conductivity of the nanowires, the cross-link directly between the overlapped nanowires or via through a small middle portion of conductive TCO film multiple current pathways are formed with higher conductivity. At the same time, with only about 2% or less in shadowing area the nanowires block very little incoming light so that the light transmission through the nanowire-enhanced structure remains high, e.g. at least 90%.

In an alternative embodiment, the nanowires 140 are covered by a second TCO film 133. The second TCO film 133 is a material substantially the same as TCO film 132 and can be formed at the same time the nanowires are sprayed onto the upper surface of the TCO film 132. As the nanowires are captured during the TCO deposition there is no need for adhesives, firing or other process step to ensure adhesion of the nanowire with the host TCO material. Both TCO film 132 and TCO film 133 can be ZnO material formed using a MOCVD process. In an alternative embodiment, the second TCO film 133 can have a higher doping level. As the nanowires are embedded in the TCO film 132 and 133, the lateral electrical conductivity is greatly enhanced, for example, up to 1000 times, and the free-carrier mobility may be enhanced by roughly 3 times. Because of the nanowires, the host TCO film 132 or 133 can be formed with substantially reduced doping level compared to the case without nanowires.

Followed by the formation of TCO film (132 or both 132 and 133) and embedded metallic nanowires 140 therein, another patterning process can be performed to create line patterns 113 which are also shifted respectively to the previously formed patterns 111 and 112, leading to a completion of an electrical coupling structure there and a formation of the top electrode in the nanowire-enhanced TCO film for collecting electric currents and connecting all stripe-shaped cells together (in parallel or in series) for the thin-film photovoltaic device 100 that formed on the substrate 101. A bonding or encapsulating material 150 is then applied overlying the nanowire-enhanced TCO film, followed by disposing a cap window glass 160 over the encapsulating material to seal the thin-film photovoltaic device 100.

The nanowire-enhanced TCO film provides several advantages. First, the film lateral conductivity can be enhanced without reduction in optical transmission. The electrical conductivity of typical MOCVD-processed zinc oxide (ZnO) is about 600 S/cm while the electrical conductivity of silver, a typical material used for forming the nanowires, is about 6×10⁵ S/cm. That is about 1000 times more in electrical conduction per unit volume. Second, adding nanowires also reduces the need for a particular doping level in TCO film. The lateral conductivity can be held constant despite the reduction of doping levels, leading to increased carrier mobility or higher conductivity per carrier. This results in larger grain structures in the TCO film which produce favorable short wavelength light scattering, and generally improves photovoltaic solar cell current generation. Third, silver has about 3 time higher free-carrier mobility than ZnO. This means less optical absorption by the free-carriers in the long wavelength region for nanowire-enhanced TCO film than for conventional TCO film (e.g., ZnO film) with equivalent electrical conductivity.

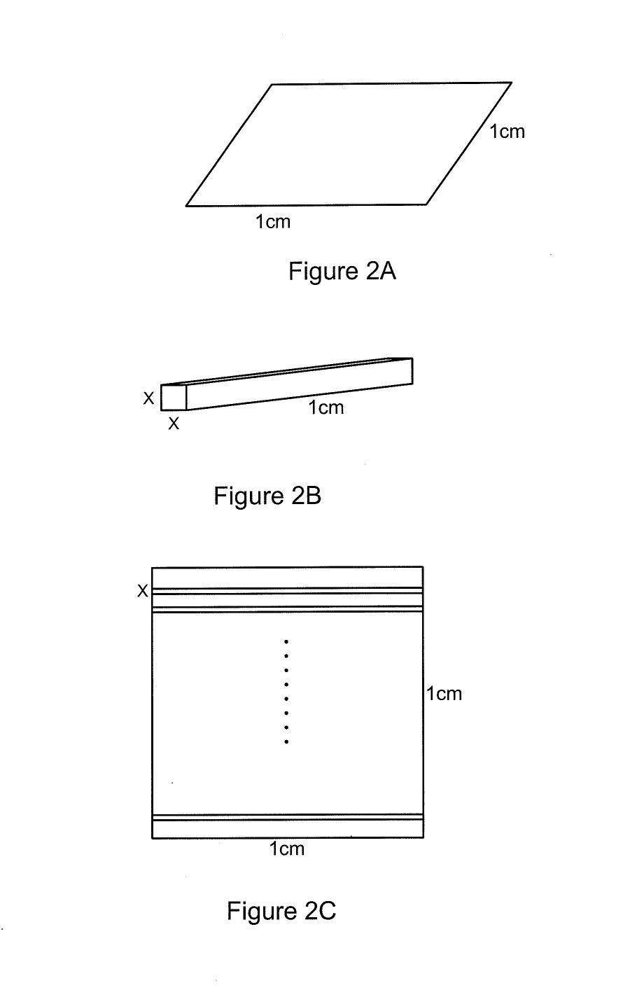

A simplified model for estimating the amount of nanowires to be incorporated in a standard 2 μm ZnO film (having a sheet resistance of 7 Ω per unit area) is discussed next. FIG. 2A illustrates a unit area of a film. The volume of the unit area film is V=2 μm×1 cm²=2×10⁻⁴ cm³. Assuming that a proportional amount of silver is incorporated into the ZnO film, since the conductivity of silver is 10³ times of conductivity of ZnO, only 10⁻³ volume is required or 2×10⁻⁷ cm³ for doubling the lateral conductivity.

If silver is in a form of a wire 1 cm in length and an X-squared cross-section, e.g. as shown in FIG. 2B. Let X be 100 nm (10⁻⁵ cm)so that it is shorter than wavelength of visible light to enhance sun light scattering, each wire has a volume V_{wire}=(10⁻⁵ cm)²×1 cm=10⁻¹⁰ cm³. Thus, a quantity of silver nanowires is estimated by dividing the total volume by the wire volume, i.e., 2×10⁻⁷ cm³/10⁻¹⁰ cm³=2000 wires.

The shadowing effect or the optical cross-section area of these wires can also be estimated. FIG. 2C is a simplified shadowing model of nanowires within a unit area of the film according to an embodiment of the present invention. Assuming that all the 2000 nanowires are aligned parallel within the unit area of the film, each wire occupies a width 100 nm and a length 1 cm. Total cross-section area is 2000×10⁻⁵ cm×1 cm=2×10⁻² cm². Thus, nominal shadowing or cross-section of the embedded nanowires in the TCO film is about 2% of a total area of the host TCO film.

Additionally, as the metallic nanowires are embedded in the host TCO film, a metal-dielectric interface is formed for each nanowire. When incident electromagnetic wave (EM) hits the interface a refraction, a transmission, and a reflection of the EM usually occurs. In addition, provided that the cross-sectional dimension or the diameter of the nanowire is in a range of hundreds of nanometers, localized surface Plasmons excitation is also induced to generate an interface wave propagation. Providing that the cross-sectional dimension or the diameter of the nanowire is about 100 nanometers or smaller while major ranges of visible spectrum is in about 350 nm to 1400 nm, so that the incoming visible light is mostly in off-resonance range upon hitting the interface of the metallic nanowire vs. the host oxide film. As the result, the EM is predominantly scattered without much absorption by the nanowires. Adding the light scattering effect around the nanowires, the effective shadowing (or absorption cross section area) of these nanowires will be smaller than actual geometrical size, providing an enhancement in overall light transmission through the nanowire-enhanced TCO Film. Other trade-offs between the sheet resistance and the optical transmission are possible by varying different wire contents and host TCO film doping levels. In another example, the nanowires are formed with asymmetrical shapes having a narrower width at its disposed position in the plane of the TCO film so that the nominal cross-section and resulted optical absorption could be further reduced.

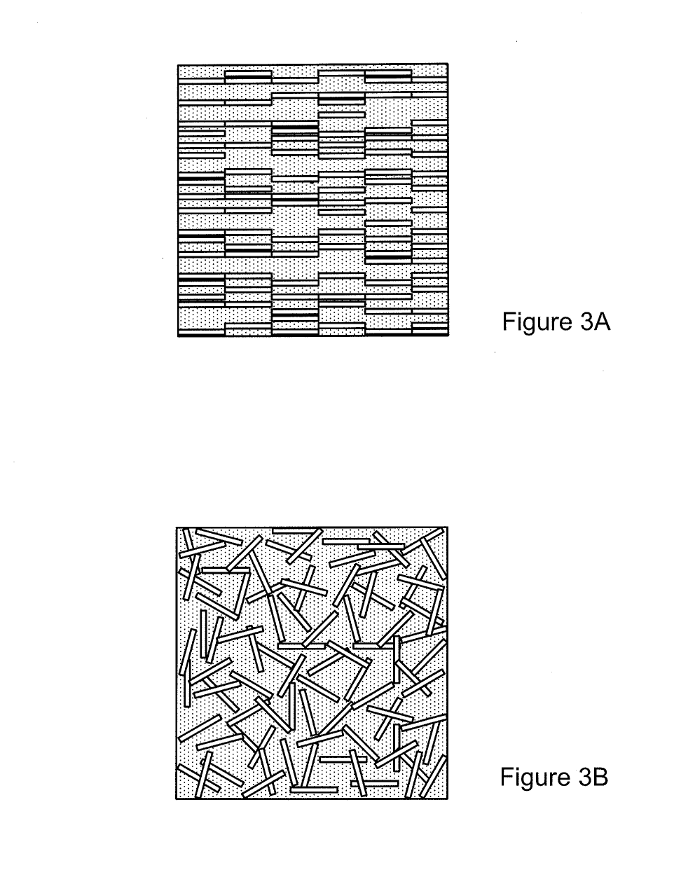

In one or more embodiments, depending on applications the nanowires can be laid out in a plane of the TCO film with various structure configurations. FIG. 3A is a top view of an exemplary layout of the nanowires on a TCO film according to an embodiment of the invention. As shown, all the nanowires are substantially parallel aligned within the plane and preferably along a predetermined PV current flow direction. These aligned nanowire structure may be formed from in situ physical/chemical deposition and patterning processes using masks. Some of the nanowires have physical cross connection to others along the length direction while some of the nanowires have no direct contact. An advantage of the aligned nanowires lies in enhancement in lateral electrical conductivity and carrier mobility with a small tradeoff in optical transmission loss. Theoretically, the metal material in nanowires causes an absorption cross section due to physical shadowing effect blocking some light from reaching the absorber material. But the benefit provided by the light scattering around the nanometer scaled structures and reduction in a thickness of the host TCO film contributes to a reduction in absorption by the carriers and an effective cross section that blocks optical transmission. In an embodiment, the effective cross section of a nanowire-enhance TCO electrode is limited to 1% or less for the incoming visible light.

FIG. 3B is a top view of another exemplary layout of the nanowires on a TCO film according to an alternative embodiment of the present invention. The nanowires, each of which is a pseudo one-dimensional nanostructure, are disposed with random orientations in the host TCO film. In an implementation, the nanowires are pre-manufactured and stored without alignment. As these nanowires are deposited on the TCO film, the random configuration is substantially retained except having their length more or less near an upper surface of the TCO film due to gravity. Some nanowires form a crossing or overlapping contact with neighboring nanowires. Some nanowires may be left without direct contact to their neighbors. In a specific embodiment, the nanowires are metallic, for example, silver or gold. In another embodiment, the nanowires are embedded into the conductive TCO film. Although some nanowires are not directly connected to their neighboring nanowires, the effective electrical conductivity associated with the nanowire-enhanced TCO film is still raised compared to a nominal TCO film.

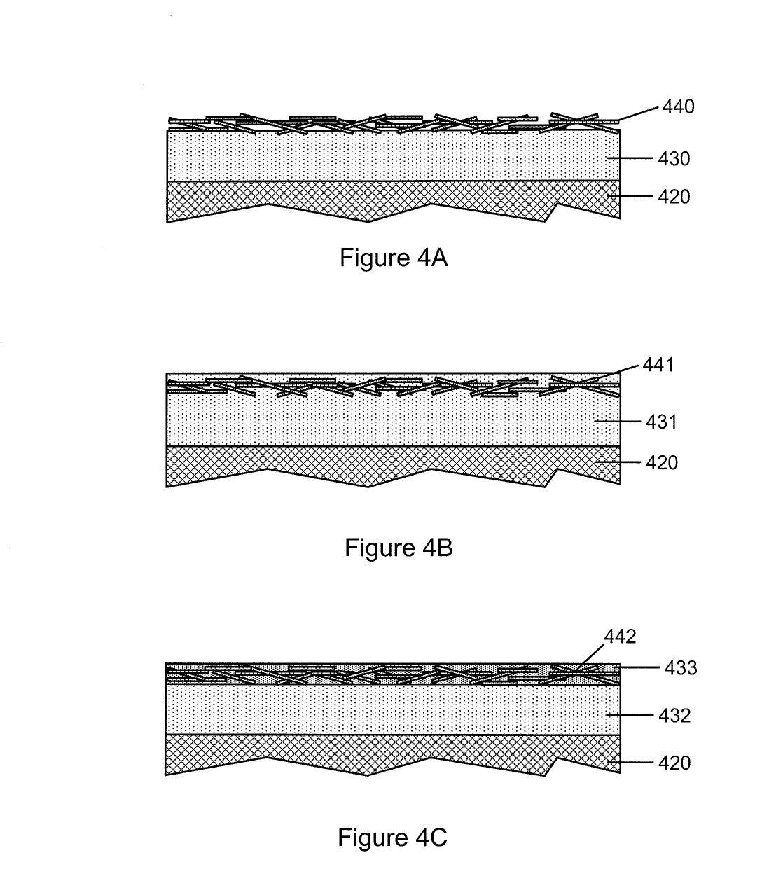

FIGS. 4A-4C are cross-sectional views of TCO films including nanowires. As shown in FIG. 4A, a portion of TCO film 430 is formed overlying a photovoltaic absorber material 420. For example, the TCO film is a zinc oxide film formed via a MOCVD process. In another example, the TCO film is a zinc oxide film doped with a small dosage of boron to form a high resistive transparent (HRT) layer bearing n-type semiconductor characteristic and a high sheet resistance ranging from 1 ohm per square to 1 milliohm per square. The benefit of the HRT layer is to serve as a protection layer which can reduce electric shorting or carrier recombination by potential pinholes or whiskers formed at the interface between the electrode layer and the photovoltaic material. The thickness of the HRT layer can be limited so that its optical transparency is still around 90% or higher for visible light. In yet another example, the TCO film is a mixture of zinc oxide and zinc sulfide material doped by boron formed by MOCVD process.

Nanowires 440 are disposed in a random configuration over the TCO film 430 with each nanowire being directly or indirectly contacted with the conductive TCO film, forming a nanowire-enhanced TCO film without adding other conductive film on top of those nanowires. Each nanowire typically has a lateral dimension of about 100 nm or less and an aspect ratio greater than 1 and usually near 1000:1. For example, pre-formed silver nanowires bearing above geometric characteristics and an electrical conductivity of about 1000 times higher than the nominal TCO film are sprayed over an upper surface of TCO film 430 for forming the nanowire-enhanced TCO film. The randomly crossed or overlapped nanowires form a mesh network providing conduction paths that have substantially higher lateral electrical conductivity than nominal TCO film itself. Additionally as mentioned earlier, by controlling an amount of the disposed nanowires the effective cross-section for light absorption associated with these nanowires can be limited to 2% or less. The relative low electrical conductivity of the HRT layer is compensated by the highly conductive nanowires while keeping the optical transparency high for the whole nanowire-enhanced TCO film.

FIG. 4B shows another example of forming the nanowire-enhanced TCO film. As shown, a first partial portion of the TCO film 431 has been pre-formed over the photovoltaic absorber material 420. The first portion of the TCO film 431 can be formed using a MOCVD process. Nanowires 441 are disposed at least partially overlying the first partial portion of the TCO film 431. In an embodiment, the nanowires 441 are substantially the same as the nanowires 440 disposed ex situ up to a predetermined coverage using a mechanical sprinkler. In another embodiment, the nanowires 441 are formed in situ using a chemical synthesis process or atomic deposition process with a controlled coverage that yields vertical cross-section of about 2% or less.

A second partial portion of the TCO film 431 is formed to embed the nanowires 441. In a specific embodiment, the second portion of the TCO film added fills the intestinal regions of a matrix of the randomly distributed nanowires. The second TCO film may be added with the disposition of the nanowires by the sprinkler. Therefore, all nanowires are captured during the TCO deposition and there is no need for adhesives, firing or other process steps to ensure adhesion. As a result, the nanowire-enhanced structure is also a TCO film with embedded nanowires. The second TCO film can be applied up to an amount for just covering the matrix of nanowires to have a minimized average thickness for the whole nanowire-enhanced TCO film. The reduced thickness of the TCO film helps retain high optical transparency. In another specific embodiment, the second partial portion of TCO film is same material used for the first partial portion of the TCO film 431, characterized by n-type doping level, resistivity level, and optical transparency.

FIG. 4C shows an alternative example of forming the nanowire-enhanced TCO film. As shown, the nanowires 442 are disposed over a first TCO film 432 and then filled by a second TCO film 433. The nanowires 442 can be the same as the nanowires 440 or 441 mentioned earlier. The first TCO film 432 is substantially the same as the TCO film 431, e.g. a zinc oxide transparent conductive film formed using a MOCVD process. The second TCO film 433 is another optical transparent conductive film but with different electric and optical properties. The second TCO film 433 can have substantially the same average thickness as the average thickness associated with the nanowires 442.

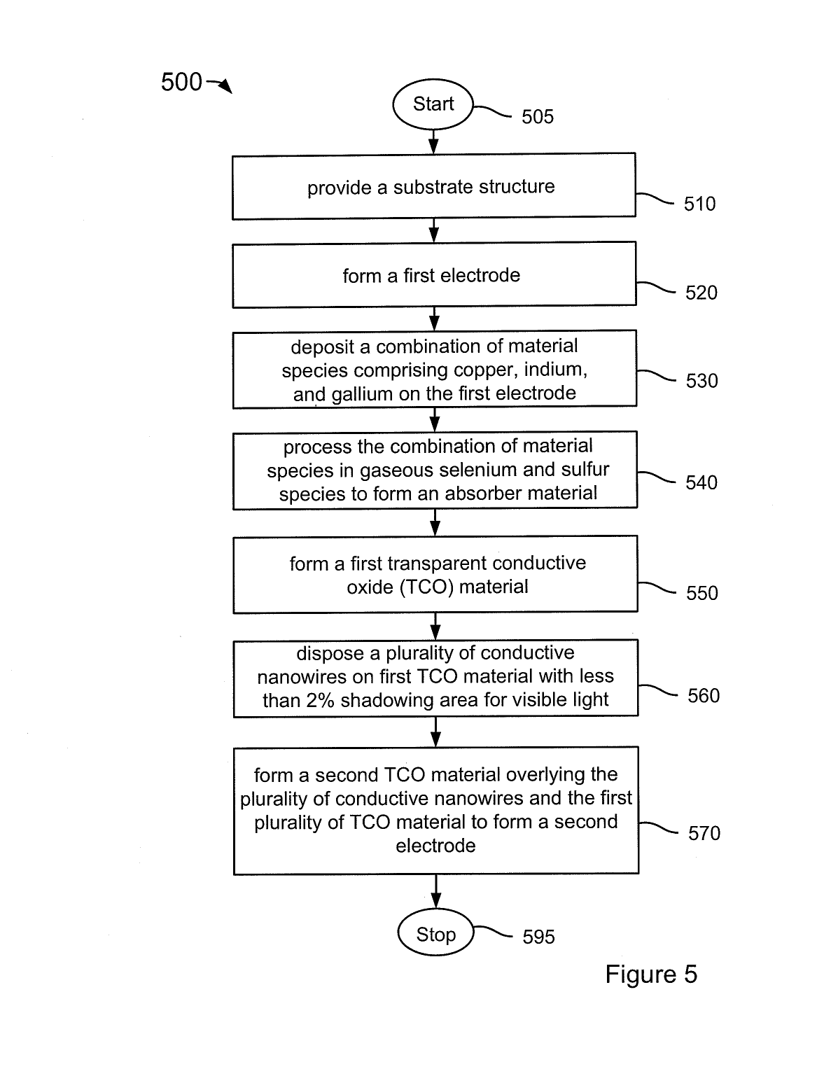

FIG. 5 is a flow chart illustrating a method for manufacturing a thin-film photovoltaic device according to an embodiment of the present invention. The examples and embodiments described herein are for illustrative purposes only and various modifications or changes in light thereof will be apparent to persons skilled in the art.

As shown in FIG. 5, the present method is:
1. Start;
2. Provide a substrate structure;
3. Form a first electrode;
4. Deposit a combination of material species comprising copper, indium, and gallium on the first electrode;
5. Process the combination of material species in gaseous selenium and sulfur species to form an absorber material;
6. Form a first transparent conductive oxide (TCO) material;
7. Dispose a plurality of conductive nanowires on the first TCO material with less than 2% shadowing area for visible light;
8. Form a second TCO material overlying the plurality of conductive nanowires and the first plurality of TCO material to form a second electrode; and
9. Stop.

As shown, the above method provides a way of enhancing lateral conductivity and free-carrier mobility of the top electrode of thin-film photovoltaic device without causing significant light shadowing effects. In a preferred embodiment, the method implements a technique to disposing nanowires with coverage over or within a transparent conductive material forming the top electrode of the thin-film photovoltaic device.

As shown in FIG. 5, the method 500 begins at start, step 505. In an embodiment, the method 500 is part of a plurality of manufacture processes for forming thin-film photovoltaic devices on one or more extra large sized substrates with various shapes and form factors.

The method 500 includes a step 520 for forming a first electrode on the substrate. For thin-film photovoltaic device, the first electrode, or back electrode, is made by a metal, metal alloy, metal oxide, or other inorganic or organic conductive materials. The conductive material is deposited, sputtered, coated, painted, or plated over the substrate. In a specific embodiment, a barrier layer is formed first overlying the bare substrate surface then the conductive material is added overlying the barrier layer. The barrier layer serves a diffusion barrier for preventing certain material species to drift into the electrode material or upper films and also serves as an adhesion or bonding material between the substrate and the first electrode. In an embodiment, the barrier layer is made by a dielectric material selected from silicon oxide, aluminum oxide, titanium nitride, silicon nitride, tantalum oxide, and zirconium oxide or the likes. Once the conductive material is formed as a film over the substrate, a patterning process can be implemented to pattern the conductive material by scribing a first plurality of line trenches across the substrate. These line trenches are formed using laser or mechanical scriber to penetrate through the film across one of the dimension of the substrate and, in one or more embodiments, are aligned in parallel with an equal spacing distributed along the other dimension of the substrate. These line patterns serve a basis for forming a plurality of electric coupling structures that couples, either in series or in parallel, a plurality of stripe-shaped cells of the thin-film photovoltaic device.

Referring to FIG. 5, the method 500 includes a step 530 for depositing a combination of material species comprising copper, indium, and gallium on the first electrode. After the formation of the back electrode, a p-n junction structure is designated for the photovoltaic device. The method 500 forms a precursor thin film material by using sputter deposition techniques. The precursor thin film material includes copper species and indium species doped with sodium species (by using specific sodium-contained copper or indium sputtering target devices). The precursor thin film material may also include gallium or aluminum species during above process to add these material species in a separated process to create a desired chemical stoichiometry. More details about forming a precursor material for forming a photovoltaic absorber in the manufacture of thin-film photovoltaic devices can be found in U.S. patent application Ser. No. 13/086,135, filed Apr. 13, 2011, assigned to Stion Corporation in San Jose and incorporated as reference for all purposes.

The method 500 further includes step 540 for processing the precursor thin film material in a gaseous environment containing selenium and/or sulfur species. In an embodiment, the process is conducted in a furnace made by material that is thermally conductive and chemically inert. The gaseous selenium species is first introduced to perform a reactive annealing of the precursor thin film material containing copper, indium, and/or gallium species following one or more stages of a predetermined temperature profile. Further, the gaseous sulfur species is introduced, with optionally removing the selenium species, to perform another reactive annealing at some additional stages of the predetermined temperature profile. A quick cooling process is followed after the second annealing process. As the result, the precursor thin film material is transformed into a photovoltaic absorber material that contain substantially a copper indium gallium selenium (CIGS) or copper indium gallium selenium sulfur (CIGSS) multi-grained compound material with a preferred composition ratio of Cu/(In+Ga) of about 0.9. The absorber material as formed bears a p-type semiconductor characteristic and an energy band-gap of about 1 eV to 1.2 eV for facilitating light absorption within a broad range of visible light band to achieve high efficiency for converting sun light into electricity energy. This is merely used as an example of many optional thin-film photovoltaic absorber materials which should not limit the scope of the claims herein. Depending on applications, there can be many variations, alternatives, and modifications. For example, additional process may be inserted after the formation of the photovoltaic absorber material, including patterning the absorber for scribing a second plurality of line trenches across the first dimension of the substrate. The second plurality of line trenches is substantially parallel to and shifted away by a pre-determined distance from the first plurality of line trenches, commonly serving basis forming the cell boundaries and cell-cell electric coupling structures.

Furthermore, the method 500 includes a step 550 of forming a first transparent conductive oxide (TCO) material overlying the absorber material. Firstly, a n-type material is needed for forming over the p-type absorber material to complete a formation of pn-junction for the thin-film photovoltaic device. A buffer layer is first formed overlying the as-formed absorber material. In a specific embodiment, the buffer material is made by chemical bath process, containing a cadmium sulfide, or zinc oxide, or zinc oxide mixed with zinc sulfide. Over the buffer layer, a first transparent conductive oxide material with n-type doped semiconductor characteristic can be formed. Both the first transparent conductive oxide material and the buffer layer are combined to serve as a window layer for completion of a p-n junction for the photovoltaic device. In another specific embodiment, the first transparent conductive oxide is doped with a relative low dosage boron species or aluminum species to have a high sheet resistance ranging from 10² to 10⁴ mΩ·cm but retain high optical transmission with greater than 90% transparency to visible light.

FIG. 5 further shows that the method 500 includes a step 560 for disposing a plurality of conductive nanowires on the first TCO material with less than 2% shadowing area for visible light. In a specific embodiment, the conductive nanowires are formed with metallic material, for example, silver, copper, with high electrical conductivity aiming for enhancing lateral conductivity as they are introduced and embedded into the host TCO film. The nanowires can be chemically synthesized or grown via atomic deposition techniques and typically have a cross-section of 100 nm or less and an aspect ratio ranging from 1:1 to 1000:1 or greater. In an embodiment, the nanowires are independently formed from certain nuclei with various possible overall configurations. For example, depending on substrate or synthesis environment, the nanowires can be formed with configurations that range from a certain degrees of parallel alignment to a substantial randomness. In another specific embodiment, the plurality of conductive nanowires or metallic nanowires can be formed in situ during the step 550 or subsequent steps. In yet another specific embodiment, the nanowires are preformed in separate processes and supplied as finished material species ready for different applications. The step 560 then performs a deposition process to dispose these nanowire species via a mechanical sprinkler onto the host TCO film up to a predetermined coverage. The metallic material by itself has a poor optical transmission for visible light. By supplying the metallic material in nanowire form and controlling the coverage of the nanowires on the host TCO film, a light shadowing effect caused by the material itself can be limited to 2% or less. The nanometer scaled feature causes mutual light scattering around these nanowires, effectively reducing a cross section of light absorption by the metallic material. At the same time, using silver or other good conductor material, the nanowires provide 1000 time enhancement in the lateral conductivity.

Moreover, as shown in FIG. 5, the method 500 includes a step 570 for forming a second TCO material overlying the plurality of conductive nanowires and the first plurality of TCO material to form a second electrode. In an embodiment, the second TCO material is optional. In a specific embodiment, the second TCO material is substantially the same the first TCO material and fills interstitial regions of the plurality conductive nanowires formed in step 560. Depending on the configuration of the plurality of conductive nanowires on the first TCO material, an average height of the nanowires can be estimated. The second TCO material is applied on such that it bears a thickness ranging from zero (i.e., TCO material is not applied) up to a thickness that substantially equal to or less than the average height. In another specific embodiment, the second TCO material is applied to allow the nanowires embedded therein and the second TCO material is substantially the same as the first TCO material but doped with relative higher level of Boron or Aluminum for reducing its sheet resistance.

In an alternative embodiment, the method 500 further includes steps for patterning the nanowire-enhanced TCO material by scribing through all films formed on the substrate to form a third plurality of line trenches. The third plurality of line trenches, in an embodiment, is substantially parallel to the first and second plurality of line trenches but shifted by another distance (see step 520 and 540). All these line trenches macroscopically divide the thin film on the substrate into multiple stripe shaped cells. The combined structures associated with all three sets of line trenches are designed as an electrical coupling structure that links two neighboring cells and subsequently all the stripe-shaped cells for the thin-film photovoltaic device. The patterning process can be performed using laser beam scribing, particle beam scribing, or mechanical scribing. Following the scribing certain refilling process of a conductive or an insulation material is performed to complete the coupling structure. Of course, there are many variations, alternatives, and modifications.

In an alternative specific embodiment, the present invention provides a method for applying a plurality of nanowire structures with a predetermined dosage in a host conductive dielectric film for fabricating a solar cell structure. According to the embodiment, a substrate structure is provided for fabricating the solar cell. The substrate structure can be a monolithically integrated glass panel, or a silicon wafer, or a wafer made from three-five group material. On the substrate structure or partially by itself, an absorber material is formed to provide an upper surface region. In a specific embodiment, the absorber material is a thin film compound material made from a copper bearing material, an indium bearing material, and a gallium bearing material. By either an in situ or an ex situ technique, a plurality of nanowire structures is applied overlying the upper surface region with a physical coverage of about 1% and greater. In an ex situ method, the pre-fabricated nanowire structures can be sprayed with a controlled deposition rate over the upper surface region by a sprinkler up to the predetermined coverage.

In an embodiment, the nanowires are pre-fabricated from silver, gold, aluminum, molybdenum, tungsten, or metal alloys. In another embodiment, the nanowires are carbon, graphite, or organic material. The nanowires have high electrical conductivity (about 100 or 1000 times greater than typical conductive dielectric material), a cross-sectional dimension or diameter of about 100 nm, and an aspect ratio ranging from near to 1:1 to 1000:1 or greater (though majority being near 1000:1 aspect ratio).

A transparent conductor material is formed over the nanowires. In an embodiment, the transparent conductor material is zinc oxide and/or ZnOₓS₁₋ₓ material formed by physical vapor deposition, chemical vapor deposition, metal-organic chemical vapor deposition, sputter deposition, and chemical bath deposition. The transparent conductor material is formed to a thickness sufficient for filling and embedding the nanowires within the thickness. In another specific embodiment, applying or spraying of the nanowires onto the upper surface region and the forming of the transparent conductor material occurs substantially simultaneously to form a nanowire-enhanced transparent conductor film.

In another specific embodiment, the plurality of nanowire structures is not only configured to have a diameter of about 100 nm and an 1000:1 aspect ratio or less for each nanowire structure but also is applied such that they are distributed in a substantially random configuration on the upper surface region except of having their lengths are more likely on the surface region due to gravitational force. The interconnect between nearest nanowires is random but still results in a formation of a conductor mesh network for facilitating electrical current flow, leading to substantial reduction in lateral resistance of the nanowire-enhanced transparent conductor film compared to the host transparent conductor material alone. Additionally, the randomly interconnected nanowire structures have a controlled low surface coverage to produce less than 2% shadowing area for the incoming light when it is acted as a top electrode for a finished solar cell. Furthermore, the nanometer scaled diameter of the nanowire structures does not causes strong excitation of surface Plasmons so that the electromagnetic waves associated with the visible light (wavelengths ranging from 350 nm to 1400 nm) are substantially scattered around the nanowire structure surfaces without being absorbed by the nanowire structures. This effective reduce the cross section area of the light absorption (smaller than physical shadowing area) by enhancing scattering of incident electromagnetic radiation while allowing the electromagnetic radiation to traverse the thickness of the transparent conductor material and be substantially free from blocking the absorber material beneath.

In an implementation of the present invention, the thickness of transparent conductor material alone is characterized by a sheet resistivity of 3 ohms/square or smaller. As the transparent conductor material is applied to embed the plurality of nanowire structures up to the thickness ranges from about 1 to 3 microns, the nanowire-enhanced transparent conductor film can have its sheet resistivity reduced 10 or 100 times smaller. This allows a low doping level in the transparent conductor material and results less free-carrier absorption of the income visible light. In a specific embodiment, the thickness of transparent conductor material including the embeded the plurality of nanowire structures is characterized by a transparency of 90% and greater transmission for incident electromagnetic radiation ranging in about 350 nm to 1400 nm.

It is understood that the examples and embodiments described herein are for illustrative purposes only and that various modifications or changes in light thereof will be suggest to persons skilled in the art and are to be included within the spirit and purview of this application and scope of the appended claims. Although the above examples have been generally described in terms of a specific thin-film photovoltaic structure with CIS, CIGS, CIGSS absorber material, other absorber materials certainly can also be applied and incorporated with a nanowire-enhanced TCO film transparent conductive top electrode, without departing from the invention described by the claims herein.

What is claimed is:

1. A thin-film photovoltaic device comprising:
an absorber material characterized by a copper-based thin-film photovoltaic compound overlying a conductive material formed on a substrate;
a buffer material overlying the absorber material;
a window layer comprising a transparent conductive oxide material overlying the buffer material; and
conductive nanowires embedded in the window layer in a substantially random configuration with less than 2% nominal shadowing area to visible light, the nanowires having an electrical conductivity substantially higher than the transparent conductive oxide material.

2. The structure of claim 1 wherein the absorber material comprises a CIS/CIGS/CIGSS compound including copper species, indium species, gallium species, selenium species, sulfur species, sodium species.

3. The structure of claim 1 wherein the buffer material comprises a cadmium sulfide (CdS) layer, cadmium-free zinc oxide (ZnO) layer, zinc sulfide (ZnS) and ZnO mixed layer.

4. The structure of claim 1 wherein the transparent conductive oxide material is characterized by a metal oxide film doped to have a sheet resistivity ranging from 10² to 10⁴ mΩ·cm.

5. The structure of claim 1 wherein the nanowires comprise nanostructures formed using chemical synthesis of at least one metal species selected from aluminum, copper, silver, gold, molybdenum, and tungsten.

6. The structure of claim 1 wherein the nanowires generally have a lateral dimension between 10 nm and 100 nm and have an aspect ratio between 1:1 and 1000:1.

7. A method for manufacturing thin-film photovoltaic devices comprising:
providing a substrate structure;
forming a barrier layer over the substrate structure;
forming a first electrode of conductive material over the barrier layer;
depositing a combination of copper, sodium, indium, and gallium on the first electrode;
forming an absorber material by heating the structure;
forming a buffer material over the absorber material;
forming a first conductive oxide over the buffer material;
disposing conductive nanowires on the first conductive oxide material; and
forming a second conductive oxide material over the nanowires.

8. The method of claim 7 wherein the step of forming the barrier layer comprises depositing a dielectric material selected from silicon oxide, aluminum oxide, titanium nitride, silicon nitride, tantalum oxide, and zirconium oxide.

9. The method of claim 7 wherein the step of forming the conductive material comprises depositing at least one layer of a metal and/or a metal oxide over the barrier layer, the metal being selected from molybdenum, tungsten, and zinc.

10. The method of claim 7 wherein the absorber material comprises a CIGS/CIGSS compound material which includes copper, indium, gallium, selenium, and sulfur.

11. The method of claim 7 wherein the step of forming a buffer material comprises performing a deposition process to apply a layer of at least one of ZnO and ZnS over the absorber material.

12. The method of claim 7 wherein the first conductive oxide material comprises a zinc oxide film doped with boron to have sheet resistivity about 3 Ω per square and greater than 90% optical transparency for visible light.

13. The method of claim 7 wherein the step of disposing nanowires comprises spraying conductive nanowires to form a randomly aligned matrix covering about 1% of the surface area of the first conductive oxide material.

14. The method of claim 13 wherein the step of forming a second conductive oxide material comprises covering the nanowires to embed them within the combined layers of first and second conductive oxide material.

15. The method of claim 13 wherein the second conductive oxide material comprises zinc oxide having substantially the same doping level of boron as the first conductive oxide material.

16. A method for fabricating a solar cell structure comprising:
providing a substrate structure;
forming an absorber material overlying the substrate structure to form an upper surface region;
applying nanowires to the upper surface region with a coverage of at least 1%;
forming transparent conductor material over the nanowires to embed them within the transparent conductor material; and
the nanowires facilitating scattering of incident electromagnetic radiation and allowing the electromagnetic radiation to traverse the thickness of the transparent conductor material.

17. The method of claim 16 wherein the nanowires comprise one of silver, gold, aluminum, molybdenum, or tungsten.

18. The method of claim 16 wherein the transparent conductor is from about 1 to 3 microns thick.

19. The method of claim 16 wherein the absorber material comprises copper, indium and gallium.

20. The method of claim 16 wherein the step of applying comprises nanowires.

21. The method of claim 16 wherein the step of applying nanowires and the step of forming of the transparent conductor material occur substantially simultaneously.

22. The method of claim 16 wherein the transparent conductor material has a sheet resistivity of less than about 3 ohms/square.

23. The method of claim 16 wherein transparent conductor material with the nanowires has a transparency of at least 90% of incident electromagnetic radiation between 350 nm and 1400 nm.

24. The method of claim 16 wherein the nanowires comprise an aligned array, a random mesh, a cross-linked matrix, or scattered individual wires.

25. The method of claim 16 wherein the nanowires comprise a material selected from metal, carbon, and organic material, and have a diameter of less than about 100 nm.

26. The method of claim 16 further comprising scribing the thickness of the transparent conductor material including the nanowires to form an electrode.
